(19) United States
(12) Patent Application Publication
(10) Pub. No.: US 2024/0255695 A1
(43) Pub. Date: Aug. 1, 2024

(54) WIRING SUBSTRATE

(71) Applicant: IBIDEN CO., LTD., Ogaki (JP)

(72) Inventor: Masatoshi KUNIEDA, Ibi-gun (JP)

(73) Assignee: IBIDEN CO., LTD., Ogaki (JP)

(21) Appl. No.: 18/632,346

(22) Filed: Apr. 11, 2024

Related U.S. Application Data
(63) Continuation of application No. PCT/JP2022/036976, filed on Oct. 3, 2022.

(30) Foreign Application Priority Data
Oct. 11, 2021 (JP) 2021-166864

(51) Int. Cl. G02B 6/12; H01L 23/00; H01L 23/538; H01L 25/16

(52) U.S. Cl. CPC G02B 6/12004; H01L 23/5386; H01L 24/13; H01L 24/16; H01L 24/05; H01L 24/11; H01L 25/167; H01L 2224/0557; H01L 2224/11462; H01L 2224/13082; H01L 2224/13111; H01L 2224/13144; H01L 2224/13147; H01L 2224/13155; H01L 2224/16227

(57) ABSTRACT

A wiring substrate includes an insulating layer, a conductor pad that is formed on a surface of the insulating layer and is connected to a component such that the insulating layer has a component region that is covered by the component connected to the conductor pad, and an optical waveguide including a core part that transmits light and is positioned on an outer side of the component region of the insulating layer such that the core part has an end surface exposed and facing a component region side. The optical waveguide is positioned such that the end surface of the core part is adjacent to the component region.

### CROSS-REFERENCE TO RELATED APPLICATIONS

The present application is a continuation of and claims the benefit of priority to International Application No. PCT/JP2022/036976, filed Oct. 3, 2022, which is based upon and claims the benefit of priority to Japanese Application No. 2021-166864, filed Oct. 11, 2021. The entire contents of these applications are incorporated herein by reference.

### BACKGROUND OF THE INVENTION

### Field of the Invention

The present invention relates to a wiring substrate.

### Description of Background Art

Japanese Patent Application Laid-Open Publication No. 2008-129385 describes an optical component mounting substrate, on a surface of which an optical waveguide and an optical semiconductor element are mounted. The entire contents of this publication are incorporated herein by reference.

### SUMMARY OF THE INVENTION

According to one aspect of the present invention, a wiring substrate includes an insulating layer, a conductor pad that is formed on a surface of the insulating layer and is connected to a component such that the insulating layer has a component region that is covered by the component connected to the conductor pad, and an optical waveguide including a core part that transmits light and is positioned on an outer side of the component region of the insulating layer such that the core part has an end surface exposed and facing a component region side. The optical waveguide is positioned such that the end surface of the core part is adjacent to the component region.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a plan view illustrating an example of a surface state of the wiring substrate of FIG. 1;

FIG. 3 is an enlarged view of a portion (III) of FIG. 1;

FIG. 4 is an enlarged view illustrating a modified example of conductor posts and an optical waveguide according to an embodiment of the present invention;

FIG. 5 is a cross-sectional view illustrating a modified example of a wiring substrate according to an embodiment of the present invention;

FIG. 6 is an enlarged view illustrating a modified example of a portion (VI) of FIG. 5;

FIG. 7 is a cross-sectional view illustrating an example of a wiring substrate according to another embodiment of the present invention;

FIG. 8A is a cross-sectional view illustrating an example of a manufacturing process of a wiring substrate according to an embodiment of the present invention;

FIG. 8B is a cross-sectional view illustrating an example of a manufacturing process of a wiring substrate according to an embodiment of the present invention;

FIG. 8C is a cross-sectional view illustrating an example of a manufacturing process of a wiring substrate according to an embodiment of the present invention;

FIG. 8D is a cross-sectional view illustrating an example of a manufacturing process of a wiring substrate according to an embodiment of the present invention;

FIG. 9A is a perspective view illustrating an example of a manufacturing process of an optical waveguide in a wiring substrate according to an embodiment of the present invention;

FIG. 9B is a perspective view illustrating an example of a manufacturing process of an optical waveguide in a wiring substrate according to an embodiment of the present invention;

FIG. 9C is a perspective view illustrating an example of a manufacturing process of an optical waveguide in a wiring substrate according to an embodiment of the present invention;

FIG. 10A is a cross-sectional view illustrating an example of a manufacturing process of a conductor post of the modified example illustrated in FIG. 4;

FIG. 10B is a cross-sectional view illustrating an example of a manufacturing process of the conductor post of the modified embodiment illustrated in FIG. 4;

FIG. 10C is a cross-sectional view illustrating an example of a manufacturing process of the conductor posts of the modified example illustrated in FIG. 4; and

FIG. 10D is a cross-sectional view illustrating an example of a manufacturing process of the conductor posts of the modified example illustrated in FIG. 4.

### DETAILED DESCRIPTION OF THE EMBODIMENTS

Embodiments will now be described with reference to the accompanying drawings, wherein like reference numerals designate corresponding or identical elements throughout the various drawings.

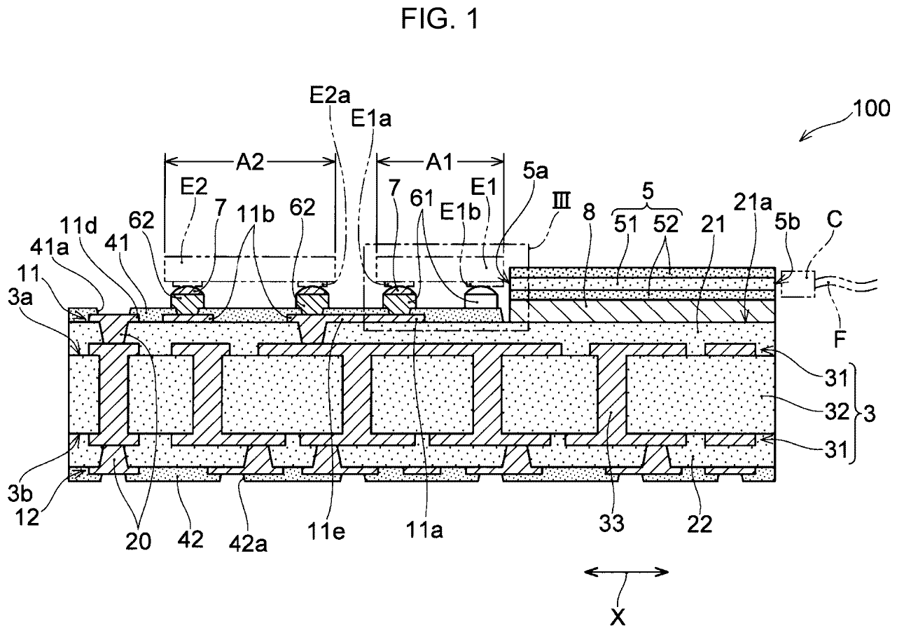

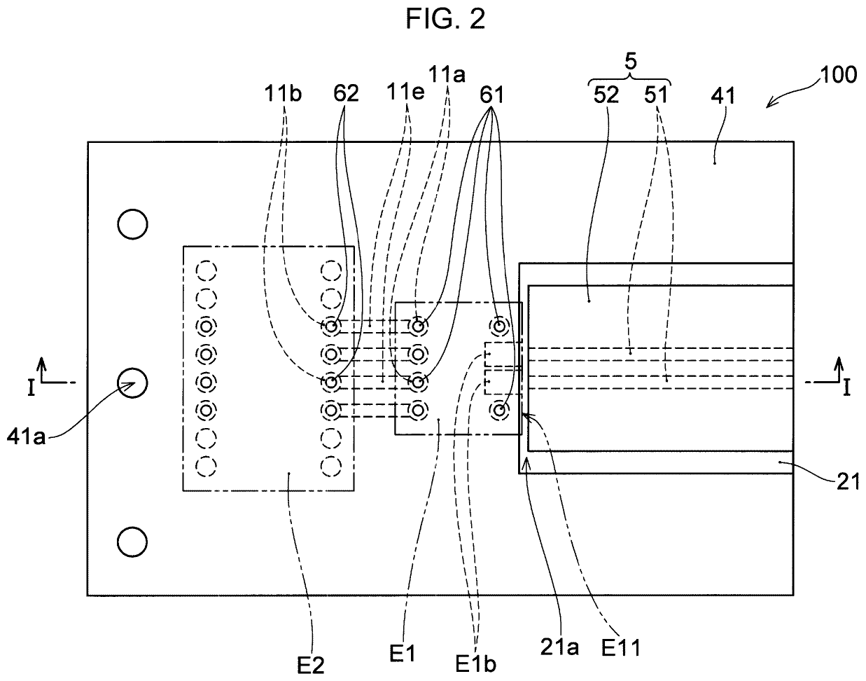

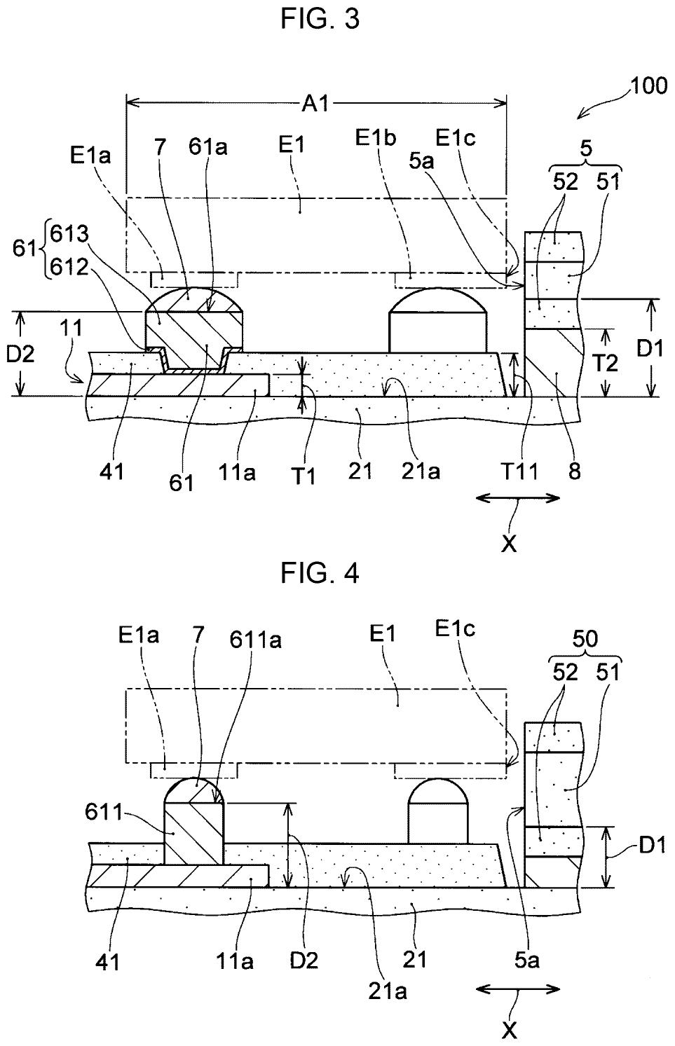

A wiring substrate according to an embodiment of the present invention is described with reference to the drawings. FIG. 1 is a cross-sectional view illustrating a wiring substrate 100 according to an embodiment of the present invention, and FIG. 2 illustrates an example of the wiring substrate 100 of FIG. 1 in a plan view (FIG. 1 is a cross-sectional view along a line (I-I) in FIG. 2). The term “plan view” means viewing the wiring substrate of the embodiment along a thickness direction thereof. FIG. 3 illustrates an enlarged view of a portion (III) of FIG. 1. A laminated structure, and the number of conductor layers and the number of insulating layers of the wiring substrate of the embodiment are not limited to the laminated structure of the wiring substrate 100 of FIG. 1, and the number of conductor layers and the number of insulating layers included in the wiring substrate 100.

As illustrated in FIG. 1, the wiring substrate 100 includes a core substrate 3, and an insulating layer and a conductor layer sequentially laminated on each of two main surfaces (a first surface (3a) and a second surface (3b)) of the core substrate 3 opposing each other in a thickness direction of the core substrate 3. The core substrate 3 includes an insulating layer 32, and conductor layers 31 that are respectively formed on both sides of the insulating layer 32. The insulating layer 32 is provided with through-hole conductors 33 that penetrate the insulating layer 32 and connects the conductor layers 31 on both sides of the insulating layer 32 to each other.

In the description of the embodiment, a side farther from the insulating layer 32 in a thickness direction of the wiring substrate 100 is also referred to as an “upper side” or simply “upper,” and a side closer to the insulating layer 32 is also referred to as a “lower side” or simply “lower.” Further, for the conductor layers and the insulating layers, a surface facing an opposite side with respect to the insulating layer 32 is also referred to as an “upper surface,” and a surface facing the insulating layer 32 side is also referred to as a “lower surface.”

The wiring substrate 100 includes an insulating layer 21 and a conductor layer 11. The insulating layer 21 is laminated on the first surface (3a) of the core substrate 3. The insulating layer 21 has a surface (21a) on an opposite side with respect to the core substrate 3, and the conductor layer 11 is formed on the surface (21a). The wiring substrate 100 in FIG. 1 further includes a covering layer 41. The covering layer 41 partially covers each of the insulating layer 21 and the conductor layer 11. The covering layer 41 is formed with openings (41a) that each expose a part of the conductor layer 11.

On the other hand, an insulating layer 22 is laminated on the second surface (3b) of the core substrate 3. A conductor layer 12 is formed on the insulating layer 22, and a solder resist 42 covering the insulating layer 22 and the conductor layer 12 is formed. The solder resist 42 is formed of, for example, a photosensitive epoxy resin or polyimide resin, or the like. The solder resist 42 is formed with openings (42a) that each expose a part of the conductor layer 12. In each of the insulating layer 21 and the insulating layer 22, via conductors 20 connecting the conductor layers that sandwich the insulating layer 21 or the insulating layer 22 to each other are formed.

The wiring substrate 100 further includes an optical waveguide 5 formed on the surface (21a) side of the insulating layer 21. The wiring substrate 100 in the example of FIGS. 1-3 further includes a spacer 8. The spacer 8 is formed on the surface (21a) of the insulating layer 21. The optical waveguide 5 is provided on a surface of the spacer 8 on an opposite side with respect to the insulating layer 21 side. That is, the optical waveguide 5 is formed on the surface (21a) of the insulating layer 21 via the spacer 8. As illustrated in FIGS. 1-3, in a plan view, the optical waveguide 5 and the spacer 8 are provided in a region on the surface (21a) of the insulating layer 21 that is not covered by the covering layer 41.

The optical waveguide 5 includes a core part 51 that transmits light and a cladding part 52 that is provided around the core part 51. The cladding part 52 sandwiches the core part 51 in any direction perpendicular to an extension direction of the core part 51, that is, a propagation direction of light in the core part 51 (hereinafter this direction is also referred to as an “X direction”). The cladding part 52 surrounds the core part 51 in a plane perpendicular to the X direction. The optical waveguide 5 is formed, for example, using a photolithography method (in which a material for the core part is patterned by exposure and development), a Mosquito method (in which a needle is caused to scan in a clad while a material for forming the core part is ejected), an imprint method, or the like. However, the method of forming the optical waveguide 5 is not limited to these methods.

The optical waveguide 5 is adhered to the surface of the spacer 8, for example, using an adhesive (not illustrated) or the like. The optical waveguide 5 and the spacer 8 may be joined by curing a material of the cladding part 52 in a semi-cured state on the spacer 8. The spacer 8 is also fixed to the surface (21a) of the insulating layer 21, for example, using an adhesive (not illustrated). However, a method for fixing the optical waveguide 5 and the spacer 8 and a method for fixing the spacer 8 and the insulating layer 21 are not particularly limited, and the optical waveguide 5 can be fixed to the spacer 8 by any measures. The spacer 8 can also be fixed to the surface (21a) of the insulating layer 21 by any measures.

The wiring substrate 100 of FIG. 1 further includes conductor posts (61, 62) formed on the conductor layer 11. The conductor posts (61, 62) are each a conductor having, for example, a columnar, frustum-like, or inverted frustum-like shape extending from the conductor layer 11 in a direction away from the insulating layer 21. The conductor posts (61, 62) protrude from a surface of the covering layer 41 on an opposite side with respect to the insulating layer 21. The conductor posts (61, 62) can each have any shape in a cross section and a surface orthogonal to the thickness direction of the wiring substrate 100. An external component (E1) is connected to the conductor posts 61, and an external component (E2) is connected to the conductor posts 62. That is, the component (E1) and the component (E2) are connected to the wiring substrate 100 when the wiring substrate 100 is used. Therefore, the wiring substrate 100 includes a component region (A1) (first component region), which is a region to be covered by the component (E1) when the wiring substrate 100 is used, and a component region (A2) (second component region), which is a region to be covered by the component (E2) when the wiring substrate 100 is used.

The component (E1) connected to the conductor posts 61 is positioned in the component region (A1), and the component (E2) connected to the conductor posts 62 is positioned in the component region (A2). On the other hand, the optical waveguide 5 is provided outside the component region (A1). Therefore, when the component (E1) is mounted in the component region (A1), the optical waveguide 5 is positioned on a lateral side of the component (E1). That is, the optical waveguide 5 is provided so as not to overlap with the component region (A1) and the component (E1) in a plan view. In other words, the component (E1) is positioned on a lateral side of the optical waveguide 5.

The insulating layers (21, 22) and the insulating layer 32 are each formed of, for example, an insulating resin such as an epoxy resin, a bismaleimide triazine resin (BT resin), or a phenol resin. Further, although not illustrated, the insulating layers each may contain a core material (reinforcing material) formed of a glass fiber, an aramid fiber, or the like, and each may contain an inorganic filler formed of fine particles of silica (SiO₂), alumina, mullite, or the like.

The covering layer 41 is formed of any insulating material. For example, the covering layer 41 may be formed of the same epoxy resin or polyimide resin as the solder resist 42 and may function as a solder resist preventing a short circuit between the conductor posts. Or, the covering layer 41 may be formed of an epoxy resin, a BT resin, or a phenol resin used for interlayer insulating layers such as the insulating layer 21 and the insulating layer 22. That is, the material of the covering layer 41 is not limited to a specific material as long as the covering layer 41 is insulating and can cover predetermined regions of the conductor layer 11 and the insulating layer 21.

The core part 51 and the cladding part 52 of the optical waveguide 5 are each formed using a material having an appropriate refractive index. The core part 51 and the cladding part 52 can each be formed of, for example, an organic material, an inorganic material, or a hybrid material, such as an inorganic polymer, containing an organic component and an inorganic component. Examples of inorganic materials include quartz glass, silicon, and the like, and examples of organic materials include acrylic resins such as polymethylmethacrylate (PMMA), polyimide resins, polyamide resins, polyether resins, epoxy resins, and the like. Further, inorganic polymers such as polysilane may be used. The core part 51 and cladding part 52 may be formed of materials different from each other or may be formed of materials of the same type.

However, for the core part 51, a material having a higher refractive index than that used for the cladding part 52 is used. Since total reflection of light incident on an interface between the core part 51 and the cladding part 52 at an incident angle equal to or larger than a critical angle is possible, light incident on the core part 51 can efficiently propagate in the core part 51. It is also possible that, after the core part 51 and the cladding part 52 are formed using materials having the same refractive index, the refractive indices of the core part 51 and the cladding part 52 are made different from each other by appropriate processing. For example, the refractive index of polysilane decreases when irradiated with ultraviolet rays.

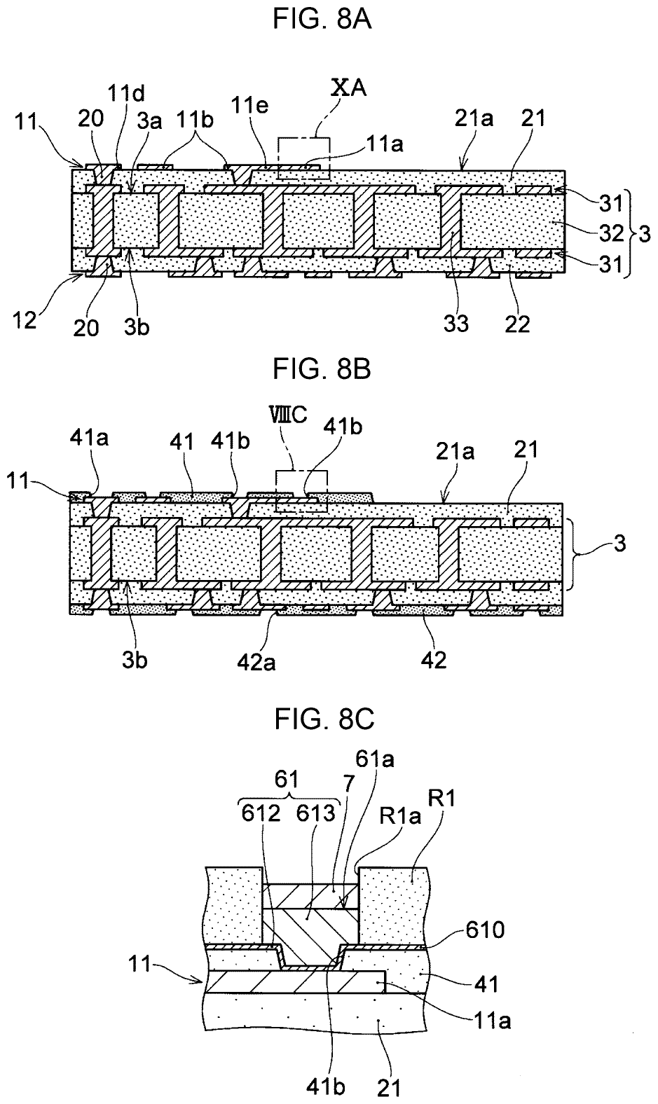

The conductor layers (11, 12) and the conductor layers 31, the through-hole conductors 33, the via conductors 20, and the conductor posts (61, 62) and conductor posts 63 (see FIG. 7) (to be described later) can be formed using any metal such as copper or nickel. In FIG. 1, these conductors are simplified and are drawn as each having a one-layer structure. However, these conductors can each have a multilayer structure including two or more film bodies as illustrated in the enlarged view of the conductor posts 61 in FIG. 3. For example, the conductor layers (11, 12) can each have a two-layer structure including an electroless plating film and an electrolytic plating film. The conductor posts (61-63) are formed, for example, of plating metal deposited by electroless plating and/or electrolytic plating.

The conductor layers (11, 12) and the conductor layers 31 can each include any conductor patterns. As illustrated in FIGS. 1-3, the conductor layer 11 includes at least conductor pads (11a) (first conductor pads). In the example of FIG. 1, the conductor layer 11 further also includes conductor pads (11b) (second conductor pads), conductor pads (11d), and wirings (11e). That is, the conductor pads (11a, 11b, 11d) and the wirings (11e) are provided on the surface (21a) of the insulating layer 21. The wirings (11e) are formed by wiring patterns included in the conductor layer 11. The conductor pads (11a) and at least one of the conductor pads (11b) are connected by the wirings (11e).

The conductor posts 61 are respectively formed on the conductor pads (11a), and the conductor posts 61 are respectively connected to the conductor pads (11a). Therefore, electrodes (E1a) of the component (E1) are physically and electrically connected to the conductor pads (11a) via the conductor posts 61. Similarly, the conductor posts 62 are respectively formed on the conductor pads (11b), and the conductor posts 62 are respectively connected to the conductor pads (11b). Therefore, electrodes (E2a) of the component (E2) are physically and electrically connected to the conductor pads (11b) via the conductor posts 62. The conductor posts 61 protrude from surfaces of the conductor pads (11a) on an opposite side with respect to the insulating layer 21 side and penetrate the covering layer 41. Similarly, the conductor posts 62 protrude from surfaces of the conductor pads (11b) and penetrate the covering layer 41.

When the wiring substrate 100 is used, an electrical component that includes a light receiving element and/or a light emitting element and has a photoelectric conversion function is mounted in the component region (A1) as the component (E1). The component (E1) in the example of FIGS. 1-3 includes a light receiving or light emitting part (E1b) in addition to the electrodes (E1a). The light receiving or light emitting part (E1b) has a light receiving or light emitting surface (E1c) (see FIG. 3) that faces to a lateral side of the component (E1). The electrodes (E1a) and the light receiving or light emitting part (E1b) are provided on a surface of the component (E1) facing the wiring substrate 100 side. That is, in the example of FIGS. 1-3, the component (E1) is mounted by so-called face-down mounting (flip-chip mounting).

Examples of the component (E1) include: light receiving elements such as a photodiode; and light emitting elements such as a light emitting diode (LED), an organic light emitting diode (OLED), a laser diode (LD), and a vertical cavity surface emitting laser (VCSEL). When the component (E1) is a light emitting element, the component (E1) generates light based on an electrical signal input to the electrodes (E1a) and emits light from the light receiving or light emitting part (E1b) that functions as a light emitting part. Further, when the component (E1) is a light receiving element, an electrical signal is generated based on light incident on the light receiving or light emitting part (E1b) that functions as a light receiving part and is output from the electrodes (E1a).

In the example of FIG. 1, the component (E2) has the electrodes (E2a) on a surface facing the wiring substrate 100 side. That is, the component (E2) is also mounted by so-called face-down mounting. The component (E2) can be an electronic component such as a semiconductor device that generates an electrical signal that causes the component (E1) to emit light, and/or processes an electrical signal generated by the component (E1). Examples of the component (E2) include semiconductor devices such as a general-purpose operational amplifier, a driver IC, a microcomputer, and a programmable logic device (PLD).

The core part 51 of the optical waveguide 5 extends along the optical waveguide 5 from one end side to the other end side thereof. The core part 51 has a first end surface (5a) on or from which light is incident or emitted, and a second end surface (5b) that is an end surface on an opposite side with respect to the first end surface (5a) and on or from which light is incident or emitted. The optical waveguide 5 is positioned such that the component region (A1) and the first end surface (5a) are adjacent to each other. “The component region (A1) and the first end surface (5a) are adjacent to each other” means that, in a plan view, there is no light shielding object between the component region (A1) and the first end surface (5a), and the component region (A1) and the first end surface (5a) are close enough that light can be transmitted and received between the component (E1) mounted in the component region (A1) and the core part 51. “Light can be transmitted and received” means that light propagates between the first end surface (5a) and the component (E1) to an extent that desired information can be obtained based on light received via the core part 51 in either the component (E1) or a light receiving element (not illustrated) connected to the second end surface (5b) side of the core part 51.

In other words, the optical waveguide 5 is positioned such that, when the component (E1) is mounted in the component region (A1), the light receiving or light emitting part (E1b) of the component (E1) and the first end surface (5a) of the core part 51 are optically coupled. Further, in the example of FIG. 1, the optical waveguide 5 is optically coupled to an external optical connector (C) connected to an optical fiber (F) at the second end surface (5b). Light propagating through the optical fiber (F) is incident on the second end surface (5b) of the core part 51 via the optical connector (C), and propagates in the core part 51, and is emitted from the first end surface (5a). The light is incident on the light receiving or light emitting part (E1b) of the component (E1) and is converted into an electrical signal by the component (E1). The electrical signal is output from the electrodes (E1a), input to the component (E2), and processed by the component (E2). Conversely, an electrical signal output from the component (E2) is input to the component (E1) via a reverse path and is converted into light. The light is emitted from the light receiving or light emitting part (E1b) of the component (E1), is incident on the first end surface (5a) of the core part 51, propagates in the core part 51, and is emitted from the second end surface (5b).

In this way, in the present embodiment, the first end surface (5a) of the core part 51 of the optical waveguide 5 is exposed facing the component region (A1), and the optical waveguide 5 is positioned such that the component region (A1) and the first end surface (5a) are adjacent to each other. Therefore, the light receiving or light emitting part (E1b) of the component (E1) mounted in the component region (A1) can face the first end surface (5a) of the core part 51, and the light receiving or light emitting part (E1b) of the component (E1) can be directly optically coupled to the core part 51. That is, the light emitted from the core part 51 is incident on the light receiving or light emitting part (E1b) through only a relatively short gap between the component (E1) and the first end surface (5a) without passing through the cladding part 52. Similarly, light emitted from the light receiving or light emitting part (E1b) is incident on the core part 51 without passing through the cladding part 52. Therefore, it is thought that the core part 51 of the optical waveguide 5 and the component (E1) can be optically coupled with high coupling efficiency. It is thought that light can propagate between the optical waveguide 5 and the component (E1) with low loss and high efficiency.

Further, in the present embodiment, there is no need to change a propagation direction of light propagating in the optical waveguide 5 in a direction along the surface (21a) of the insulating layer 21, and thus, there is no need to provide a reflector or the like in the optical waveguide 5. Therefore, the optical waveguide 5 can be simplified in structure, and manufacturing of the optical waveguide 5 can be facilitated. In this way, according to the present embodiment, it is thought that the core part of the optical waveguide, which is provided on the surface of the insulating layer having the conductor pads, and a component connected to the conductor pads can be optically coupled with a high coupling efficiency.

In the example of FIGS. 1-3, as illustrated in FIG. 2, the optical waveguide 5 has two parallel core parts 51. In this way, the optical waveguide 5 provided in the wiring substrate of the embodiment can have multiple core parts 51. Further, as illustrated in FIG. 2, the multiple wirings (11e) are provided. The multiple conductor pads (11a) and the multiple conductor pads (11b) are connected by the multiple parallel wirings (11e). In the example of FIGS. 1 and 2 and the like, the conductor posts 61 are respectively formed on the conductor pads (11a), and the conductor posts 62 are respectively formed on the conductor pads (11b). Therefore, it is thought that a short-circuit failure is unlikely to occur between adjacent conductor pads (11a) or between adjacent conductor pads (11b). Therefore, it may be possible that the multiple wirings (11e) can be formed, for example, at a narrow pitch such as a pitch of 10 μm or less.

In the example of FIGS. 1-3, there are no conductor posts 61 formed at positions corresponding to directly below the light receiving or light emitting part (E1b) of the component (E1). However, in particular, as illustrated in FIG. 2, there are conductor posts 61 formed along one side (E11) of the component (E1) adjacent to the light receiving or light emitting part (E1b), at positions near the one side (E11). Therefore, the component (E1) can be held without significant tilting.

In the example of FIGS. 1-3, a distance (D1) between the first end surface (5a) and the surface (21a) of the insulating layer 21 is larger than a thickness (T1) of the conductor pads (11a). Therefore, when the component (E1) is mounted on the conductor pads (11a) in the component region (A1), the first end surface (5a) and the component (E1) can face each other.

Further, as described above, the optical waveguide 5 in the example of FIGS. 1-3 is provided in a region outside the component region (A1), in a region of the surface (21a) of the insulating layer 21 that is not covered by the covering layer 41. Further, as illustrated in FIG. 3, the distance (D1) between the first end surface (5a) and the surface (21a) of the insulating layer 21 is larger than a thickness (T11) of the covering layer 41. Therefore, as in the example of FIGS. 1-3, even when the component (E1) is mounted on the conductor posts 61 that penetrate the covering layer 41 in the component region (A1), the first end surface (5a) can face the component (E1).

Preferably, the first end surface (5a) faces the light receiving or light emitting surface (E1c) facing a lateral side of the component (E1) in the light receiving or light emitting part (E1b) of the component (E1), in a direction along the surface (21a), that is, in the X direction. For example, by adjusting a thickness of the cladding part 52, which is positioned closer to the insulating layer 21 than the core part 51 is, and/or a thickness of the spacer 8, the first end surface (5a) and the light receiving or light emitting surface (E1c) can face each other entirely or partially.

The “distance (D1)” is a shortest distance between the surface (21a) and a boundary between the core part 51 and the cladding part 52 of the optical waveguide 5 at the first end surface (5a) in a vertical direction of the surface (21a) of the insulating layer 21. Further, the thickness (T11) of the covering layer 41 is not a thickness of a portion of the covering layer 41 covering the conductor layer 11 but is a thickness of a portion of the covering layer 41 in contact with the surface (21a) of the insulating layer 21. That is, the thickness (T11) of the covering layer 41 is a distance between the surface (21a) of the insulating layer 21 and the surface (upper surface) of the covering layer 41 on an opposite side with respect to the insulating layer 21.

In this way, in the example of FIGS. 1-3, the first end surface (5a) is farther away from the surface (21a) of the insulating layer 21 than the upper surfaces of the conductor pads (11a) are. In particular, in the example of FIGS. 1-3, the first end surface (5a) is farther away from the surface (21a) of the insulating layer 21 than the upper surface of the covering layer 41 is. Therefore, the light receiving or light emitting surface (E1c) of the component (E1) mounted on the conductor posts 61 and the first end surface (5a) of the core part 51 can face each other. Therefore, it is thought that the core part 51 of the optical waveguide 5 and the component (E1) mounted on the conductor posts 61 can be optically coupled with high coupling efficiency.

Further, in the example of FIGS. 1-3, as described above, since the conductor posts 61 are formed on the conductor pads (11a), a short circuit failure between adjacent conductor pads (11a) is unlikely to occur, and the wirings (11e) (see FIG. 1) may be formed at a narrow pitch. Further, when solder bumps or the like are used for mounting the component (E1) on the wiring substrate 100, since the conductor posts 61 are provided, it may be possible that small solder bumps, that is, solder bumps with low heights and narrow widths can be used. Therefore, it may be possible that the conductor pads (11a) can be formed closer to each other compared to a case where the conductor posts 61 are not formed. Therefore, it may be possible that a component (E1) having multiple electrodes (E1a) formed at a narrower pitch can be mounted. Further, since a change in impedance due to bumps is smaller compared to a case where large bumps are used, it may be possible that better high frequency transmission characteristics can be obtained. That is, according to the example of FIGS. 1-3, it may be possible that it can contribute to realization of densification and good high frequency characteristics of the wiring substrate.

As described above, a height of the optical waveguide 5 from the surface (21a) of the insulating layer 21 can be adjusted, for example, by the spacer 8. Specifically, a height of the core part 51 of the optical waveguide 5 from the surface (21a) is adjusted by the thickness of the spacer 8. That is, the spacer 8 is a complementary material that compensates for an insufficient height of the core part 51 of the optical waveguide 5 alone with respect to a predetermined height. Further, the spacer 8 can also be referred to as a filler that fills a gap between the optical waveguide 5 including the core part 51 positioned at a predetermined height and the surface (21a) of the insulating layer 21. Further, the spacer 8 may be formed of a base material that is used as a base for the optical waveguide 5 when the optical waveguide 5 is manufactured. That is, the base material may be used as the spacer 8 without being separated from the optical waveguide 5 after the formation of the optical waveguide 5 is completed. From this point of view, the spacer 8 can also be referred to as a base material. The spacer 8 can have a plate-like shape as illustrated in FIGS. 1-3. Further, depending on a size of the optical waveguide 5, the spacer 8 may 8 may have a rod-like or block-like shape rather than a plate-like shape.

The spacer 8 can be formed of a material having any electrical and physical properties, such as a conductor, an insulator, or a semiconductor. For example, the spacer 8 can be a semiconductor substrate formed of an elemental semiconductor such as silicon or germanium, or a compound semiconductor such as silicon oxide or gallium arsenide. The spacer 8 may also be formed of, for example, an insulating resin such as an epoxy resin or phenol resin, an inorganic insulator such as alumina or aluminum nitride, or a conductor (metal) such as copper or nickel. The spacer 8 is not particularly limited in shape or material as long as the spacer 8 can support the optical waveguide 5 at a predetermined height so that light can be incident on or emitted from the core part 51 at a desired height.

When the optical waveguide 5 alone allows the core part 51 to be positioned at a desired height on the surface (21a) of the insulating layer 21, it is also possible that the spacer 8 is not provided in the wiring substrate 100. For example, in FIG. 1, when the cladding part 52, which is positioned closer to the insulating layer 21 side than the core part 51 is, has a thickness that includes the thickness of the spacer 8 in FIG. 1, it is also possible that the spacer 8 is not provided.

With reference to FIG. 3, the optical waveguide 5, the spacer 8, and the conductor posts 61 are further described. The description with respect to the conductor posts 61 can also be applied to the conductor posts 62. As illustrated in FIG. 3, the component (E1) is mounted on end surfaces (61a) of the conductor posts 61 on an opposite side with respect to the insulating layer 21. On the other hand, the cladding part 52 is interposed between the spacer 8 and the core part 51. In the wiring substrate 100 in the example of FIG. 3, a thickness (T2) of the spacer 8 is smaller than a distance (D2) between the end surface (61a) of each of the conductor posts 61 and the surface (21a) of the insulating layer 21. Therefore, it may be possible that the first end surface (5a) of the core part 51 and the light receiving or light emitting surface (E1c) of the component (E1) can easily face each other in the X direction.

The conductor posts 61 in the example of FIG. 3 each have a two-layer structure including a lower layer 612 and an upper layer 613. The lower layer 612 is, for example, a metal film formed by electroless plating or sputtering. The upper layer 613 is, for example, an electrolytic plating film formed by electrolytic plating using the lower layer 612 as a power feeding layer. The conductor posts 61 each have, in the covering layer 41, a tapered portion that tapers toward a conductor pad (11a). Therefore, it may be possible that the conductor posts 61 and the electrodes (E1a) of the component (E1) can be connected with a larger area than a connection area between the conductor posts 61 and the conductor pads (11a).

As illustrated in FIG. 3, the wiring substrate 100 further includes a connection layer 7. The connection layer 7 is formed on the end surfaces (61a) of the conductor posts 61. The connection layer 7 is formed of a material having a lower melting point than the conductor posts 61. Therefore, the connection layer 7 can contribute to the connection between the conductor posts 61 (or the conductor posts 62) and the component (E1) (or the component (E2)). Examples of the material of the connection layer 7 include tin-based solder, gold-based solder, and the like. In the wiring substrate 100 including the connection layer 7, when the component (E1) or the component (E2) is mounted, it may be possible that supply of a bonding material such as solder can be omitted.

As illustrated in FIG. 3, the first end surface (5a) of the core part 51 of the optical waveguide 5 is farther away from the surface (21a) of the insulating layer 21 than the end surfaces (61a) of the conductor posts 61 are. Therefore, as in the example of FIG. 3, even when the connection layer 7 is formed on the end surfaces (61a) of the conductor posts 61, it is thought that the first end surface (5a) and the light receiving or light emitting surface (E1c) of the component (E1) can easily face each other in the X direction. In FIG. 3, there is a gap below the component (E1) or a gap between the component (E1) and the first end surface (5a) of the core part 51 of the optical waveguide 5. However, the gaps may be filled with resin. When the gaps are filled with resin, the gap below the component (E1) and the gap between the component (E1) and the first end surface (5a) of the core part 51 of the optical waveguide 5 may be filled with the same resin or may be respectively filled with different resins.

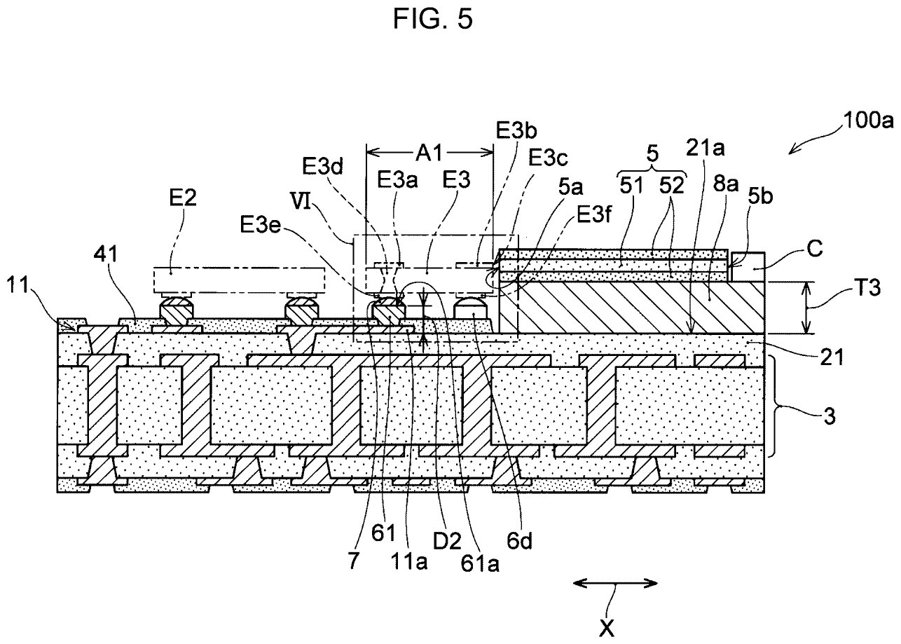

FIG. 4 illustrates conductor posts 611, which are a modified example of the conductor posts 61 of FIGS. 1-3, and an optical waveguide 50, which is a modified example of the optical waveguide 5. As illustrated in FIG. 4, the conductor posts 611 each have a substantially constant width from the conductor pads (11a) side to an opposite side with respect to the conductor pads (11a) side, that is, to the side facing the component (E1) when the wiring substrate 100 is used. Further, the conductor posts 611 are each integrally formed. That is, in the example of FIG. 4, the conductor posts 611 are each entirely integrally formed of, for example, an electrolytic plating film. In each of the conductor posts 611 in FIG. 4, for example, there is no interface between different materials or interface between regions formed at different times. In this way, it is thought that, in the conductor posts 611, which are each entirely integrally formed with a substantially constant width, a crack or interfacial peeling due to stress concentration is unlikely to occur.

Further, in the example of FIG. 4, the distance (D1) between the first end surface (5a) of the core part 51 of the optical waveguide 50 and the surface (21a) of the insulating layer 21 is smaller than the distance (D2) between an end surface (611a) of each of the conductor posts 611 on an opposite side with respect to the insulating layer 21 and the surface (21a) of the insulating layer 21. However, the light receiving or light emitting surface (E1c) of the component (E1) mounted on the conductor posts 611 faces the first end surface (5a) of the core part 51 in the X direction. In this way, the distance between the first end surface (5a) and the surface (21a) can be set according to the size of the core part 51, the thickness of the cladding part 52, and the presence or absence and thickness of the connection layer 7, such that the light receiving or light emitting surface (E1c) of the component (E1) and the first end surface (5a) of the core part 51 at least partially face each other. In other words, a magnitude relationship between the distance between the first end surface (5a) of the core part 51 and the surface (21a) of the insulating layer 21, and the distance between the end surface (611a) of each of the conductor posts 611 (or the end surface (61a) of each of the conductor posts 61 in the example of FIG. 3) and the surface (21a) can be arbitrarily set.

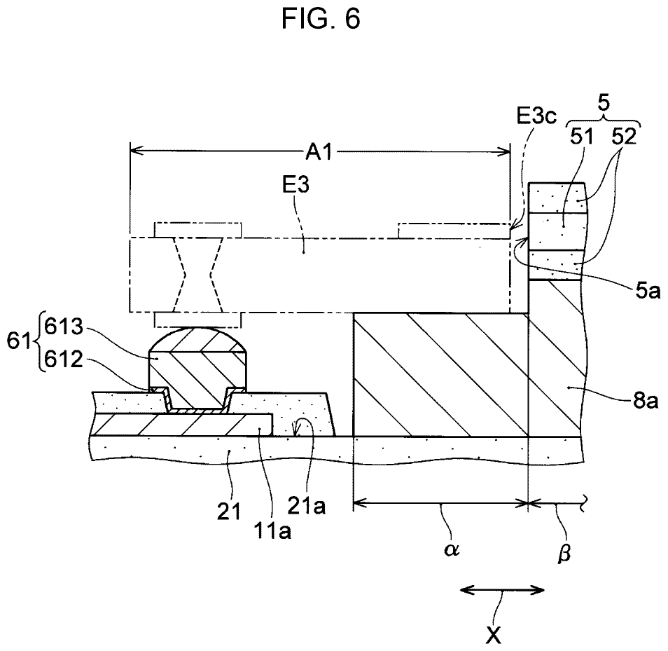

FIG. 5 illustrates a wiring substrate (100a), which is a modified example of the wiring substrate of the embodiment. A component (E3) is mounted in the component region (A1) of the wiring substrate (100a) in the example of FIG. 5. As illustrated in FIG. 5, the component (E3) is mounted with electrodes (E3a) and a light receiving or light emitting part (E3b) facing an opposite direction to the wiring substrate (100a). That is, the wiring substrate (100a) may be suitable for a case where a component having a photoelectric conversion function to be mounted in the component region (A1) is mounted in a so-called face-up manner.

In the wiring substrate (100a), the optical waveguide 5 is placed on a spacer (8a) formed on the surface (21a) of the insulating layer 21. The height of the core part 51 of the optical waveguide 5 from the surface (21a) is different from that in the example of FIG. 1. That is, the spacer (8a) has a thickness larger than the thickness of the spacer 8 in FIG. 1. Therefore, a distance between the end surface (5a) of the core part 51 and the surface (21a) in the wiring substrate (100a) is larger than the distance between the end surface (5a) of the core part 51 and the surface (21a) in the wiring substrate 100 of FIG. 1. In the example of FIG. 5, a thickness (T3) of the spacer (8a) is larger than the distance (D2) between the end surface (61a) of each of the conductor posts 61 on an opposite side with respect to the insulating layer 21 and the surface (21a) of the insulating layer 21. Therefore, the light receiving or light emitting part (E3b) of the component (E3) mounted on the end surfaces (61a) of the conductor posts 61 and the core part 51 of the optical waveguide 5 placed on the spacer (8a) can easily face each other in the X direction. Specifically, a light receiving or light emitting surface (E3c) facing a lateral side in the light receiving or light emitting part (E3b) and the first end surface (5a) of the core part 51 can easily face each other. The optical waveguide 5 and the component (E3) can be easily optically coupled with good coupling efficiency. Also in the example of FIG. 5, instead of providing the spacer (8a), the cladding part 52, which is positioned closer to the insulating layer 21 side than the core part 51 is in FIG. 5, may have a thickness that includes the thickness (T3) of the spacer (8a) in FIG. 5.

In the example in FIG. 5, the component (E3) includes through electrodes (E3d) and connection electrodes (E3e), which are connected to the electrodes (E3a), allowing the component (E3) to be suitable for face-up mounting. The connection electrodes (E3e) are provided on the surface of the component (E3) facing the wiring substrate (100a) at positions opposing the electrodes (E3a). The connection electrodes (E3e) are connected to the conductor posts 61 via the connection layer 7. The through electrodes (E3d) electrically connect the electrodes (E3a) and the connection electrodes (E3e). The through electrodes (E3d) may be, for example, through silicon vias (TSV).

Further, in the example of FIG. 5, the optical connector (C) is formed together with the optical waveguide 5 on a surface of the spacer (8a) facing away from the insulating layer 21. The optical waveguide 5 and the optical connector (C) are positioned such that a light receiving or light emitting part (not illustrated) of the optical connector (C) and the second end surface (5b) of the core part 51 of the optical waveguide 5 face each other. As in the example of FIG. 5, any component other than the optical waveguide 5, such as the optical connector (C), may be placed on the surface of the spacer (8a) (and the spacer 8 in FIG. 1) together with the optical waveguide 5.

The wiring substrate (100a) in the example of FIG. 5 includes dummy posts (6d) formed similarly to the conductor posts 61, and the component (E3) further includes dummy electrodes (E3f) on a surface facing the wiring substrate (100a). The dummy posts (6d) are in contact with the dummy electrodes (E3f), and thereby, the component (E3) is supported. Therefore, the component (E3) can be held without significant tilting. The example illustrated in FIG. 5 has a similar structure to the example illustrated in FIG. 1 except for the thickness of the spacer (8a) (the height of the core part 51), the mounting of the optical connector (C), and the structure and mounting method of the component (E3). In FIG. 5, a structural element that is the same as a structural element illustrated in FIG. 1 is indicated using the same reference numeral symbol as the one used in FIG. 1 or is omitted as appropriate, and a repetitive description of the structural element is omitted.

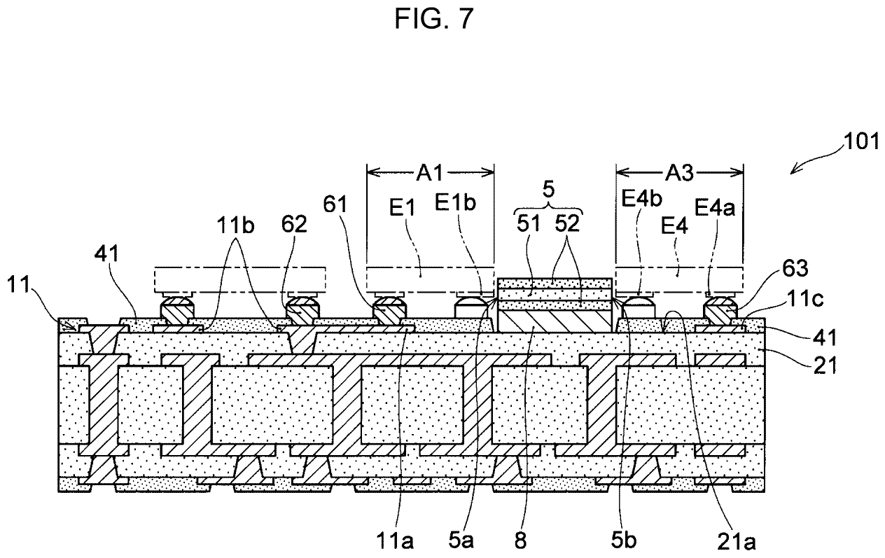

FIG. 6 illustrates an enlarged view of a portion corresponding to a portion (VI) of FIG. 5 in a further modified example of FIG. 5. The example illustrated in FIG. 6 differs from the example of FIG. 5 in that the component (E3) is partially placed on the spacer (8a). Since structural elements other than the component (E3) and the spacer (8a) are the same as in the example of FIG. 5, the same reference numeral symbols as those in FIG. 5 are assigned to those same structural elements, and redundant descriptions thereof are omitted.

The spacer (8a) illustrated in FIG. 6 has a region (α) where the optical waveguide 5 is not placed on a surface facing away from the insulating layer 21. The region (α) is closer to the surface (21a) of the insulating layer 21 than a region (β) where the optical waveguide 5 is placed is. That is, the surface of the spacer (8a) facing away from the insulating layer 21 has a step between the region (α) and the region (β). The spacer (8a) is formed on the insulating layer 21 such that at least a part of the region (α) overlaps with the component region (A1) in a plan view.

As illustrated in FIG. 6, the component (E3) is mounted on the conductor posts 61 and the region (α) of the spacer (8a). Due to the step between region (a) and region (β), the first end surface (5a) of the core part 51 of the optical waveguide 5 and the light receiving or light emitting surface (E3c) of the component (E3) face each other in the X direction. In the example of FIG. 6, the dummy posts (6d) and the dummy electrodes (E3f) of the component (E3) illustrated in FIG. 5 are not provided. However, the component (E3) is supported by the region (α), and thus can be held without significant tilting. In this way, in the wiring substrate of the embodiment, a spacer such as the spacer (8a) on which the optical waveguide is placed may have a region for supporting a component mounted in a component region.

FIG. 7 illustrates a wiring substrate 101, which is an example of a wiring substrate of another embodiment. Except for matters described below, the wiring substrate 101 is formed of the same structural elements as the wiring substrate 100 of the embodiment illustrated in FIG. 1 and the like and has the same structure as the wiring substrate 100. A structural element that is the same as a structural element of the wiring substrate 100 is indicated in FIG. 7 using the same reference numeral symbol as in FIG. 1, or is omitted as appropriate in FIG. 7, and repeated description thereof is omitted.

As illustrated in FIG. 7, similar to the wiring substrate 100 of FIG. 1, the wiring substrate 101 includes the optical waveguide 5, which includes the core part 51 and the cladding part 52, the core part 51 having the first end surface (5a) and the second end surface (5b). Similar to the optical waveguide 5 in the example of FIG. 1, the optical waveguide 5 in the example of FIG. 7 is provided in a region not covered by the covering layer 41 outside the component region (A1) on the surface (21a) of the insulating layer 21.

The conductor layer 11 of the wiring substrate 101 includes conductor pads (11c) (third conductor pads) in addition to the conductor pads (11a) and the conductor pads (11b). That is, the third conductor pads (11c) are further provided on the surface (21a) of the insulating layer 21. The conductor posts 63 are respectively formed on the conductor pads (11c) and are respectively connected to the conductor pads (11c). Similar to the conductor posts (61, 62), the conductor posts 63 are each a conductor having a columnar, frustum-like, or inverted frustum-like shape extending from the conductor layer 11 in a direction away from the insulating layer 21. The conductor posts 63 respectively protrude from upper surfaces of the conductor pads (11c) and penetrate the covering layer 41.

As illustrated in FIG. 7, when the wiring substrate 101 is used, an external component (E4) is connected to the conductor posts 63. Specifically, electrodes (E4a) of the component (E4) are connected to the conductor posts 63. Therefore, the component (E4) is physically and electrically connected to the conductor pads (11c) via the conductor posts 63. Further, the wiring substrate 101 includes a component region (A3) (third component region), which is a region to be covered by the component (E4) when the wiring substrate 101 is used. The component (E4) is positioned in the component region (A3).

Similar to the component (E1), the component (E4) is an electrical component that includes a light receiving element and/or a light emitting element and has a photoelectric conversion function. The light receiving element or the light emitting element described above regarding the component (E1) is mounted on the wiring substrate 101 as the component (E4). Therefore, the component (E4) includes a light receiving or light emitting part (E4b) in addition to the electrodes (E4a). The electrodes (E4a) and the light receiving or light emitting part (E4b) are provided on a surface of the component (E4) facing the wiring substrate 101 side. That is, in the example of FIG. 7, the component (E4) is mounted by so-called face-down mounting.

In the example of FIG. 7, the optical waveguide 5 is provided outside the component region (A3). The optical waveguide 5 is provided between the component region (A1) and the component region (A3). Also in the example of FIG. 7, the first end surface (5a) of the core part 51 of the optical waveguide 5 is exposed from the optical waveguide 5 facing the component region (A1). On the other hand, in the example of FIG. 7, the second end surface (5b), which is the end surface on an opposite side with respect to the first end surface (5a), of the core part 51 is exposed from the optical waveguide 5 facing the component region (A3) side. That is, the second end surface (5b) is exposed from the optical waveguide 5 so as to face the component (E4) when the wiring substrate 101 is used. The second end surface (5b) is positioned to face a light receiving or light emitting surface (which faces a lateral side of the component (E4)) of the light receiving or light emitting part (E4b) of the component (E4) when the wiring substrate 101 is used. In FIG. 7, there is a gap below the component (E4) or a gap between the component (E4) and the second end surface (5b) of the core part 51 of the optical waveguide 5. However, the gaps may be filled with resin. When the gaps are filled with resin, the gap below the component (E4) and the gap between the component (E4) and the second end surface (5b) of the core part 51 of the optical waveguide 5 may be filled with the same resin or may be respectively filled with different resins.

In the wiring substrate 101, the optical waveguide 5 is positioned such that the component region (A1) and the first end surface (5a) are adjacent to each other, and the component region (A3) and the second end surface (5b) are adjacent to each other. Further, also in the wiring substrate 101, the distance between the first end surface (5a) and the surface (21a) of the insulating layer 21 is larger than the thickness of the conductor pads (11a) and the thickness of the covering layer 41. The distance between the second end surface (5b) and the surface (21a) of the insulating layer 21 is also larger than the thickness of the conductor pads (11c) and the thickness of the covering layer 41. Therefore, similar to the above description regarding the first end surface (5a) of the optical waveguide 5 and the light receiving or light emitting part (E1b) of the component (E1), it may be possible that the second end surface (5b) of the optical waveguide 5 and the light receiving or light emitting part (E4b) of the component (E4) can be optically coupled with high coupling efficiency. Further, since the conductor posts 63 are formed on the conductor pads (11c), it may be possible that densification and good high frequency characteristics of the wiring substrate are realized.

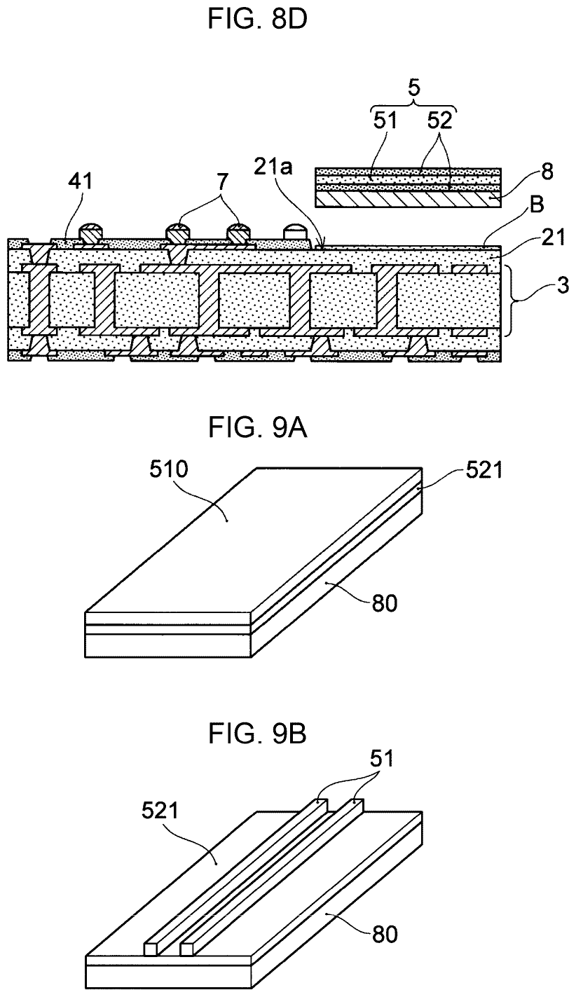

Next, a method for manufacturing the wiring substrate of the embodiment is described with reference to FIGS. 8A-8D, using the wiring substrate 100 of FIG. 1 as an example.

As illustrated in FIG. 8A, the insulating layers (21, 22) and the conductor layers (11, 12) are formed on both sides of the core substrate 3. For example, the conductor layers 31, which have desired conductor patterns, and the through-hole conductors 33 are formed using a subtractive method on or in a double-sided copper-clad laminated substrate including an insulating layer that is to become the insulating layer 32 of the core substrate 3. Then, the insulating layer 21 is formed on the first surface (3a) of the core substrate 3, and the insulating layer 22 is formed on the second surface (3b) of the core substrate 3. The insulating layer 21 and the insulating layer 22 are each formed, for example, by laminating and thermocompression bonding a film-like epoxy resin on the core substrate 3. Through holes for forming the via conductors 20 are formed in the insulating layers, for example, by irradiation with CO₂ laser or the like. Then, the conductor layer 11 is formed on the surface (21a) of the insulating layer 21, and the conductor layer 12 is formed on the insulating layer 22. The conductor layer 11 is formed to include the conductor pads (11a, 11b, 11d) and the wirings (11e). The conductor layer 11 and the conductor layer 12 are each formed using, for example, a semi-additive method.

As illustrated in FIG. 8B, the covering layer 41 is formed. The covering layer 41 is formed, for example, by supplying a liquid or sheet-like epoxy resin, polyimide resin, or the like on the surface (21a) of the insulating layer 21 and on the conductor layer 11 thereon using a method such as printing, coating, spraying, or laminating. For example, a photosensitive epoxy resin or polyimide resin is used. The covering layer 41 is fully cured or temporarily cured by heating or UV irradiation or the like when necessary. On the second surface (3b) side of the core substrate 3, the solder resist 42 is formed by coating or laminating an epoxy resin or a polyimide resin.

Then, for example, by exposure and development, or laser processing, or the like, the openings (41a) and openings (41b) are formed in the covering layer 41, and a portion of the covering layer 41 corresponding to a region where the optical waveguide 5 (see FIG. 1) is to be provided is removed. A region of the surface (21a) of the insulating layer 21 where the optical waveguide 5 is to be provided is exposed. The openings (41b) are formed at positions where the conductor posts 61 (see FIG. 8C) are to be formed. The openings (42a) are also formed in the solder resist 42.

As illustrated in FIG. 8C, a metal film 610 forming the lower layer 612 of the conductor posts 61 is formed, for example, by electroless plating or sputtering. FIG. 8C illustrates an enlarged view of a portion corresponding to a portion (VIIIC) of FIG. 8B. The metal film 610 is formed on the covering layer 41, on inner wall surfaces of the openings (41b), and on the surface of the insulating layer 21 that is not covered by the covering layer 41. Then, a plating resist (R1) having openings (R1a) exposing the openings (41b) is formed. For example, the plating resist (R1) contains a photosensitive resin, and the openings (R1a) are formed by exposure and development. Although not illustrated, the plating resist (R1) is formed so as to also cover the openings (41a) of the covering layer 41 (see FIG. 8B).

In the openings (R1a) and in the openings (41b), a metal forming the upper layer 613 is deposited by electrolytic plating. The metal film 610 can be used as a power feeding layer. As a result, the conductor posts 61 each having a two-layer structure including the lower layer 612 and the upper layer 613 are formed. Further, the connection layer 7 is formed on the end surface (61a) of the conductor posts 61 by electrolytic plating using the metal film 610 as a power feeding layer. As the connection layer 7, for example, a metal film formed of tin, a tin alloy, a gold alloy, or the like is formed. After that, the plating resist (R1) is removed using a suitable peeling agent. The metal film 610 exposed by the removal is removed by quick etching or the like.

As illustrated in FIG. 8D, the optical waveguide 5 placed on the spacer 8 is prepared. As described above, the optical waveguide 5 is formed, for example, using a photolithography method, a Mosquito method, or an imprint method, or the like. The optical waveguide 5 may be formed on a spacer 8 formed of, for example, a semiconductor substrate, as described below, or may be bonded on a separately prepared spacer 8 using any adhesive (not illustrated) after forming the core part 51 and cladding part 52.

For example, any adhesive (B), such as a thermosetting, room temperature curable, or photocurable adhesive, is supplied to a predetermined portion of the surface (21a) of the insulating layer 21 exposed from the covering layer 41, and the spacer 8 with the optical waveguide 5 is mounted thereon. When necessary, a curing treatment of the adhesive (B) by heating or the like is performed, and the spacer 8 is fixed. Further, the connection layer 7 is once melted by a reflow process or the like and is shaped into a hemispherical shape. Through the above processes, the wiring substrate 100 in the example of FIG. 1 is completed.

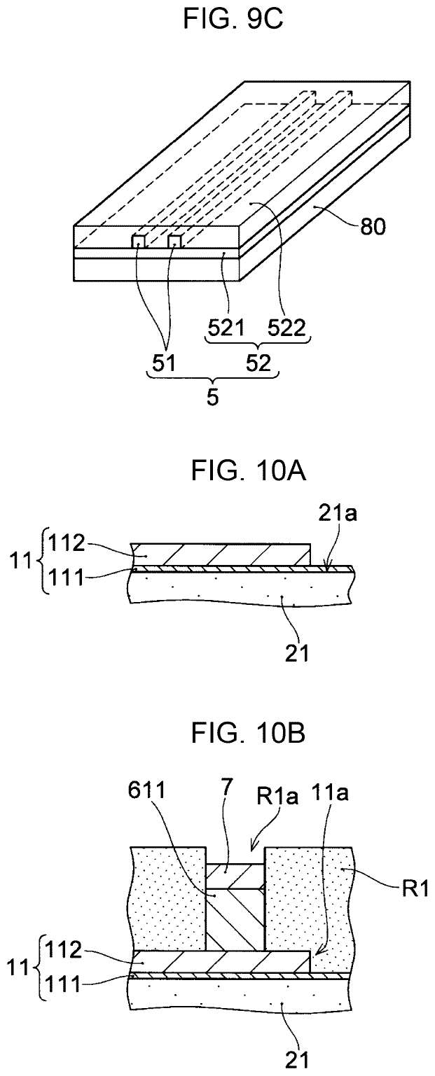

FIGS. 9A-9C illustrate, as an example, a manufacturing process of the optical waveguide 5 using a photolithography method. In the example of FIGS. 9A-9C, the optical waveguide 5 is formed using a base material 80 that will become the spacer 8 illustrated in FIG. 8D. The base material 80 can be prepared using any of the materials described above regarding the spacer 8. For example, a semiconductor substrate is prepared as the base material 80. As illustrated in FIG. 9A, a lower cladding layer 521 is formed on a surface of the base material 80. For example, a material described above as a material forming the cladding part 52 (see FIG. 8D), such as PMMA, is molded into a film and is thermocompression bonded to the base material 80. Further, a photosensitive core layer 510 is formed on the lower cladding layer 521. The core layer 510 is formed, for example, using a material described above as a material forming the core part 51 (see FIG. 8D), such as PMMA. For example, the material forming the core part 51 is molded into a film and is thermocompression bonded onto the lower cladding layer 521.

The core layer 510 is patterned and, as illustrated in FIG. 9B, the core part 51 is formed. Exposure and development with respect to the core layer 510 is performed using an exposure mask (not illustrated) having an opening corresponding to the core part 51. An unwanted portion of the core layer 510 is removed and a core part 51 having a predetermined width is formed.

As illustrated in FIG. 9C, an upper cladding layer 522 is formed on the lower cladding layer 521 and the core part 51. For example, similar to the formation of the lower cladding layer 521, a material forming the cladding part 52, such as PMMA, is molded into a film and is thermocompression bonded to the lower cladding layer 521 and the core part 51. As a result, the upper cladding layer 522 covering the core part 51 is formed. That is, the cladding part 52 formed of the lower cladding layer 521 and the upper cladding layer 522 is formed. The optical waveguide 5 including the core part 51 and the cladding part 52 is completed on the base material 80.

The base material 80 with the optical waveguide 5 on a surface thereof can be directly positioned as the spacer 8 together with the optical waveguide 5 on the surface (21a) of the insulating layer 21 in the process illustrated in FIG. 8D referenced above. Or, it is also possible that the optical waveguide 5 completed on the base material 80 is separated from the base material 80 and is fixed, for example, using an adhesive, on a surface of a separately prepared spacer 8. Further, it is also possible that the optical waveguide 5 separated from the base material 80 is fixed, using an adhesive or the like, on a surface of a spacer 8 that is separately prepared and independently positioned on the surface (21a) of the insulating layer 21.

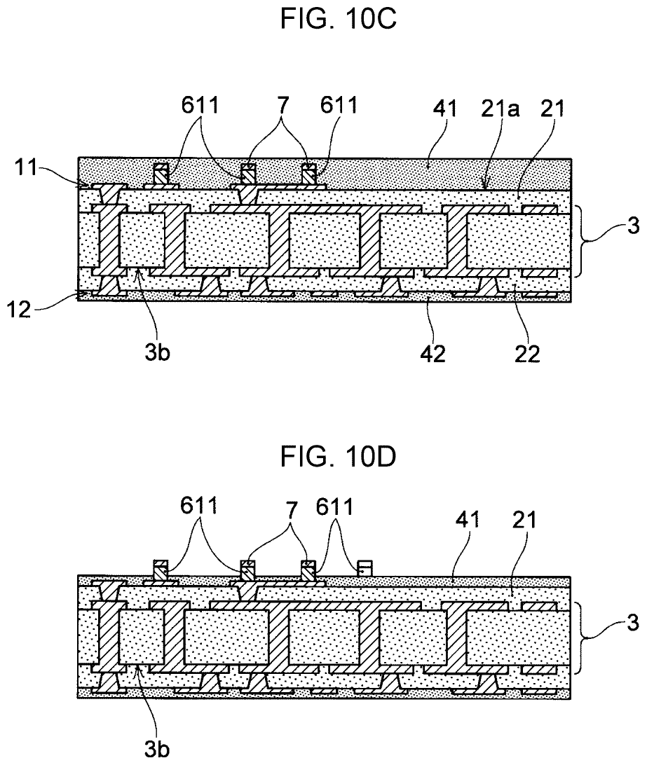

The method for forming the conductor posts 611 illustrated in FIG. 4 referenced above is described below with reference to FIGS. 10A-10D. FIG. 10A illustrates an enlarged view of a portion (XA) of FIG. 8A. In the formation of the conductor layer 11 and the like using a semi-additive method, as illustrated in FIG. 10A, for example, a metal film 111 is formed on the surface (21a) of the insulating layer 21 by electroless plating or sputtering. A plating film 112 is formed by pattern plating including electrolytic plating using the metal film 111 as a power feeding layer. When the conductor posts 611 in the example of FIG. 4 are formed, the conductor posts 611 are formed with the metal film 111 remained entirely.

As illustrated in FIG. 10B, on the conductor layer 11 and the insulating layer 21, a platting resist (R1) having openings (R1a) at formation sites of the conductor posts 611 is formed. Then, in the openings (R1a), for example, the conductor posts 611 are respectively formed by electrolytic plating using the metal film 111 as a power feeding layer. The conductor posts 611 are formed so as to have a height allowing the conductor posts 611 to penetrate the covering layer 41 when the formation of the covering layer 41 is completed in a subsequent process (see FIG. 10D), preferably, a height allowing the conductor posts 611 to protrude from the upper surface of the covering layer 41.

Further, as the connection layer 7, a metal film formed of tin, a tin alloy, a gold alloy, or the like is formed. The connection layer 7 can be formed by electrolytic plating using the metal film 111 as a power feeding layer. After the formation of the connection layer 7, the plating resist (R1) is removed. Then, a portion of the metal film 111 that is exposed by the removal of the plating resist (R1), that is, a portion that is not covered by the plating film 112 is removed, for example, by quick etching. The conductor patterns of the conductor layer 11, such as the conductor pads (11a), are physically and electrically separated from other conductor patterns.

As illustrated in FIG. 10C, the covering layer 41 covering the insulating layer 21 and the conductor layer 11, the conductor posts 611, and the connection layer 7 is formed. At the stage illustrated in FIG. 10C, the covering layer 41 is formed to cover all the structural elements on the surface (21a) of the insulating layer 21, including the conductor posts 611 and the connection layer 7.

The covering layer 41 may be formed using the same method as described with reference to FIG. 8B or may be formed by injection molding using an appropriate mold. On the second surface (3b) side of the core substrate 3, the solder resist 42 is formed by coating or laminating an epoxy resin or a polyimide resin, and the conductor layer 12 and the insulating layer 22 are entirely covered by the solder resist 42.

As illustrated in FIG. 10D, a portion of the covering layer 41 in the thickness direction is removed such that end portions of the conductor posts 611 on an opposite side with respect to the insulating layer 21 are exposed together with the connection layer 7 from the covering layer 41. Specifically, a portion of the covering layer 41 having a predetermined thickness from a surface of the covering layer 41 on an opposite side with respect to the insulating layer 21 is entirely removed. Due to the reduction in the thickness of the covering layer 41, the end portions of the conductor posts 611 on an opposite side with respect to the insulating layer 21 are exposed from the covering layer 41.

A portion of the covering layer 41 in the thickness direction can be removed, for example, by dry etching such as plasma etching using a carbon tetrafluoride (CF₄) gas. Further, it is also possible that a portion of the covering layer 41 is removed by blasting. Although not illustrated in the drawings, surfaces on the second surface (3b) side of the core substrate 3 may be protected, for example, by applying a protective film such as a film formed of polyethylene terephthalate (PET) during the formation of the conductor posts 611 and/or during the removal of a portion of the covering layer 41. For example, through the above processes, the conductor posts 611 in the example of FIG. 4 are formed.

When the spacer (8a) in the example of FIG. 6 is used, the region (α) is provided on the surface of the spacer (8a) using any method. For example, the region (α) is provided by removing a part near the surface of the spacer (8a) by mechanical processing such as polishing. The region (α) may be formed in a state in which the optical waveguide 5 is not positioned on the surface of the spacer (8a) or may be formed while removing a part of the optical waveguide 5 together with a part of the spacer (8a) in a state in which the optical waveguide 5 is positioned on the surface of the spacer (8a).

The wiring substrate of the embodiment is not limited to those having the structures illustrated in the drawings and those having the structures, shapes, and materials exemplified herein. As described above, the wiring substrate of the embodiment can have any laminated structure. For example, the wiring substrate of the embodiment may be a coreless substrate that does not include a core substrate. The wiring substrate of the embodiment can include any number of conductor layers and any number of insulating layers. Further, as described above, it is also possible that the spacer (8, 8a) is not provided. It is also possible that the conductor pads (11b) and the conductor posts 62 for mounting the component (E2) are not formed. Therefore, it is also possible that the component region (A2) is not included. Further, it is also not always necessary to provide the covering layer 41 and the conductor posts 61.

Japanese Patent Application Laid-Open Publication No. 2008-129385 describes an optical component mounting substrate, on a surface of which an optical waveguide and an optical semiconductor element are mounted. The optical waveguide having a light receiving or emitting part at one end side and a light emitting part (or light receiving part) of the optical semiconductor element are optically coupled at the other end side of the optical waveguide. Light emitted from the optical semiconductor element is incident on a core part of the optical waveguide and propagates to the light receiving and emitting part, and light incident from outside on the light receiving and emitting part propagates through the core part and is incident on the optical semiconductor element from the other end side.

In the substrate in Japanese Patent Application Laid-Open Publication No. 2008-129385, light propagating from the light receiving or emitting part or the optical semiconductor element changes its propagation direction by 90 degrees in the optical waveguide and propagates to the optical semiconductor element or the light receiving or emitting part. Therefore, a light path conversion part is formed at the other end side of the optical waveguide. It is thought that a reflector or the like is required in the optical path conversion part. Further, a cladding layer of the optical waveguide is interposed between the core part and the optical semiconductor element. Therefore, since a distance between the core part and the optical semiconductor element is large and, in addition, light propagates in any direction in the cladding layer, it is thought that a high efficiency in optical coupling is unlikely to be obtained.

A wiring substrate according to an embodiment of the present invention includes: an insulating layer that has a surface having a first conductor pad; a first component region that is a region to be covered by a component connected to the first conductor pad; and an optical waveguide that includes a core part for transmitting light and is provided on an outer side of the first component region. The core part has a first end surface exposed facing the first component region side. The optical waveguide is positioned such that the first component region and the first end surface are adjacent to each other.

According to an embodiment of the present invention, it is thought that the structure of the optical waveguide provided in the wiring substrate can be simplified and efficiency of the optical coupling between the optical waveguide and the component can be improved.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an insulating layer;
a conductor pad formed on a surface of the insulating layer and configured to be connected to a component such that the insulating layer has a component region configured to be covered by the component connected to the conductor pad; and
an optical waveguide comprising a core part configured to transmit light and positioned on an outer side of the component region of the insulating layer such that the core part has an end surface exposed and facing a component region side,
wherein the optical waveguide is positioned such that the end surface of the core part is adjacent to the component region.

2. The wiring substrate according to claim 1, further comprising:
a conductor post comprising plating metal and formed on the conductor pad,
wherein the end surface of the core part in the optical waveguide is farther away from the surface of the insulating layer than an end surface of the conductor post on an opposite side with respect to the insulating layer.

3. The wiring substrate according to claim 1, further comprising:
a conductor post comprising plating metal and formed on the conductor pad,
wherein a distance between the end surface of the core part in the optical waveguide and the surface of the insulating layer is smaller than a distance between an end surface of the conductor post on an opposite side with respect to the insulating layer and the surface of the insulating layer.

4. The wiring substrate according to claim 1, further comprising:
a spacer positioned on the surface of the insulating layer such that the optical waveguide is positioned on the surface of the insulating layer via the spacer.

5. The wiring substrate according to claim 1, further comprising:
a covering layer formed such that the covering layer is partially covering the insulating layer and that the optical waveguide is positioned in a region of the surface of the insulating layer that is not covered by the covering layer.

6. The wiring substrate according to claim 1, further comprising:
a second conductor pad formed on the surface of the insulating layer and configured to be connected to a second component; and
a wiring formed on the surface of the insulating layer such that the wiring is connecting the second conductor pad and the conductor pad,
wherein the insulating layer has a second component region configured to be covered by the second component electrically connected to the second conductor pad.

7. The wiring substrate according to claim 1, further comprising:
a third conductor pad formed on the surface of the insulating layer and configured to be connected to a third component such that the insulating layer has a third component region configured to be covered by the third component electrically connected to the third conductor pad,
wherein the optical waveguide is formed such that a second end surface of the core part on an opposite side with respect to the end surface faces a third component region side and is exposed from the optical waveguide.

8. The wiring substrate according to claim 7, further comprising:
a second conductor pad formed on the surface of the insulating layer and configured to be connected to a second component; and
a wiring formed on the surface of the insulating layer such that the wiring is connecting the second conductor pad and the conductor pad,
wherein the insulating layer has a second component region configured to be covered by the second component electrically connected to the second conductor pad.

9. The wiring substrate according to claim 1, further comprising:
a conductor post comprising plating metal and formed on the conductor pad such that the conductor post is integrally formed with a substantially constant width from a conductor pad side to an opposite side with respect to the conductor pad side.

10. The wiring substrate according to claim 1, further comprising:
a conductor post comprising plating metal and formed on the conductor pad; and
a connection layer formed on an end surface of the conductor post on an opposite side with respect to the insulating layer and comprising material having a lower melting point than the conductor post.

11. The wiring substrate according to claim 4, wherein the spacer comprises material comprising at least one of a conductor, an insulator, and a semiconductor.

12. The wiring substrate according to claim 4, further comprising:
a conductor post comprising plating metal and formed on the conductor pad such that a thickness of the spacer is larger than a distance between an end surface of the conductor post on an opposite side with respect to the insulating layer and the surface of the insulating layer.

13. The wiring substrate according to claim 1, further comprising:
a dummy post formed on the insulating layer.

14. The wiring substrate according to claim 1 further comprising:
a dummy post formed on the insulating layer and configured to support the component connected to the conductor pad,
wherein the dummy post is configured to be in contact with a dummy electrode of the component.

15. The wiring substrate according to claim 2, further comprising:
a spacer positioned on the surface of the insulating layer such that the optical waveguide is positioned on the surface of the insulating layer via the spacer.

16. The wiring substrate according to claim 2, further comprising:
a covering layer formed such that the covering layer is partially covering the insulating layer and that the optical waveguide is positioned in a region of the surface of the insulating layer that is not covered by the covering layer.

17. The wiring substrate according to claim 2, further comprising:
a second conductor pad formed on the surface of the insulating layer and configured to be connected to a second component; and
a wiring formed on the surface of the insulating layer such that the wiring is connecting the second conductor pad and the conductor pad,
wherein the insulating layer has a second component region configured to be covered by the second component electrically connected to the second conductor pad.

18. The wiring substrate according to claim 2, further comprising:
a third conductor pad formed on the surface of the insulating layer and configured to be connected to a third component such that the insulating layer has a third component region configured to be covered by the third component electrically connected to the third conductor pad,
wherein the optical waveguide is formed such that a second end surface of the core part on an opposite side with respect to the end surface faces a third component region side and is exposed from the optical waveguide.

19. The wiring substrate according to claim 18, further comprising:
a second conductor pad formed on the surface of the insulating layer and configured to be connected to a second component; and
a wiring formed on the surface of the insulating layer such that the wiring is connecting the second conductor pad and the conductor pad,
wherein the insulating layer has a second component region configured to be covered by the second component electrically connected to the second conductor pad.

20. The wiring substrate according to claim 2, further comprising:
a conductor post comprising plating metal and formed on the conductor pad such that the conductor post is integrally formed with a substantially constant width from a conductor pad side to an opposite side with respect to the conductor pad side.
